(19) United States
(12) Patent Application Publication
(10) Pub. No.: US 2008/0080259 A1
(43) Pub. Date: Apr. 3, 2008

(54) 6 Transistor Memory Circuit Pair Supporting Simultaneous Read/Write and Method Therefore

(75) Inventors: Stefan Buettner, Sindelfingen (DE); Juergen Pille, Stuttgart (DE); Otto Wagner, Altdorf (DE); Dieter Wendel, Schocnaich (DE)

Correspondence Address: INTERNATIONAL BUSINESS MACHINES CORPORATION, IPLAW DEPARTMENT, 2455 SOUTH ROAD - MS P386, POUGHKEEPSIE, NY, 12601, US

(73) Assignee: INTERNATIONAL BUSINESS MACHINES CORPORATION, Armonk, NY (US)

(21) Appl. No.: 11/862,235

(22) Filed: Sep. 27, 2007

(30) Foreign Application Priority Data
Oct. 2, 2006 (EP) 06121618.0

(51) Int. Cl. G11C 7/00

(52) U.S. Cl. 365/189.04

(57) ABSTRACT

A method and memory circuit comprising a plurality of cells accessible by word lines and bit lines is described, wherein each cell includes a group of six transistors adapted to both store a bit inserted into the cell during a write operation and affect a signal asserted during a read operation on a bit line coupled to the cell such that the affected signal matches a value of the bit stored in the cell, wherein the word lines and bit lines of the memory are divided into sections assigned to groups of equal numbers of cells, wherein said sections are individually accessible for read or write operations such that one cell of a group can be read simultaneously while writing another cell of the group.

### FIELD OF THE INVENTION

The invention relates to a method to improve performance of a memory comprising a plurality of cells accessible by word lines and bit lines plus a memory to be used to perform such a method.

### BACKGROUND OF THE INVENTION

Access to the cache memory is the operation in micro-processors which defines at most system performance. Simultaneous access to two addresses of the cache enhances system performance therefore. Especially in systems with out of order processing simultaneous read and write of two addresses of the cache improves overall performance by 10%. Dual port cells, e.g. cells that include a group of eight transistors, all the design of arrays with dual access but on expense of density.

Memories with a higher density, e.g., memories comprising cells that include a group of six transistors adapted to both store a bit inserted into the cell during a write operation and affect a signal asserted during a read operation on a bit line coupled to the cell such that the affected signal matches a value of the bit stored in the cell, up to now do not perform simultaneous access to two addresses of the cache.

### SUMMARY OF THE INVENTION

It is therefore an object of the invention to provide a method to improve the performance of a memory comprising a plurality of cells of which each one includes a group of six transistors, plus a memory with an increased performance.

An object of the invention is met by a method to improve performance of a memory comprising a plurality of cells accessible by word lines and bit lines, wherein each cell includes a group of six transistors adapted to both store a bit inserted into the cell during a write operation and affect a signal asserted during a read operation on a bit line coupled to the sell such that the affected signal matches a value of the bit stored in the cell, wherein said method comprises the steps of subdividing the bit lines of the memory into sections assigned to groups of equal numbers of cells, wherein said sections are individually accessible for read or write operations, accessing too cells belonging to different groups simultaneously by simultaneously accessing two different sections of the same bit line, and performing a write or a read operation in a cell belonging to a first group and performing a write or a read operation in a cell belonging to a second group simultaneously.

Preferably the sections of a bit line are connected with a global bit line and global write-lines via connectors. The connector is the interconnection of all cells of a group of cells assigned to the particular section of the bit line belonging to said connector. The connector is enabled with the high order address of the word line addresses of the group of cells assigned to the particular section of the bit line belonging to said connector.

Said method with the specifying features of claim 1 has the advantage over the state of the art. that it improves performance of a memory including cells comprising six transistors significantly since it allows to access two cells of the memory simultaneously.

In a preferred embodiment of said method according to the invention, different operations are performed in the selected cells, so that a write operation is performed in a cell belonging to the first group, and a read operation is performed in a cell belonging to the second group or vice-versa. Thereby it does not matter in which group a write- and in which group a read-operation is performed as long as different operations are performed in different groups.

In another preferred embodiment of said method according to the invention, accessing two cells belonging to different groups simultaneously is performed by using high-order-addresses each one assigned to a particular section of a bit line, wherein each section of a bit line is assigned to a particular group of cells. The high-order-addresses come with addressing the word lines within a particular group of cells. Thereby the group itself as well as a connector connecting global bit-lines and write-lines with the section of a bit line assigned to said group are selected by the same high-order-address.

According to an additional preferred embodiment of the method according to the invention, in order to perform a write or a read operation in a cell belonging to a first group and performing a write or a read operation in a cell belonging to a second group simultaneously, the high-order address used to select a particular section of the bit line is used as a disable reset command in a way, that the reset stays active for unselected sections, and wherein the reset command is split in two commands and the split commands are combined with high-order addresses for read and/or write.

Preferably each section of a bit line is connected to global bit- and write-lines via dedicated connectors. Thereby the sections of bit lines within a column via their connectors are connected with the global bit- and write-lines of that particular column. Each connector in a bit line column drives to the common global bit line of that column or receives signals from the global write-lines of that column on the first hand and serves a group of e.g. sixteen cells on the second hand. According to a preferred embodiment of the invention, a first connector performs a write operation whilst a second one performs a read operation. In order to select a particular cell, furthermore write- and read-addresses are decoded out of the memory's write-address- and read-address-port and logically combined in an OR function, whereas the connectors are selected either by the high-order read- or the high-order write-address.

Another object of the invention is met by a memory to be used to perform a method mentioned above, said memory comprising a plurality of cells accessible by word lines and bit lines, wherein each cell includes a group or six transistors adapted to both store a bit inserted into the cell during a write operation and affect a signal asserted during a read operation on a bit line coupled to the cell such that the affected signal matches a value of the bit stored in the cell, wherein the bit lines are subdivided into sections assigned to groups of equal numbers of cells. Thereby said sections are individually accessible for read or write operations. The memory further comprises means to simultaneously address two sections of the bit line with word line addresses of different high-order to simultaneously access two different groups of cells in order to simultaneously perform a write or a read operation in a cell belonging to a first group and performing a write or a read operation in a cell belonging to a second group.

In a preferred embodiment of said memory according to the invention, said means to simultaneously address two sections of the bit line comprise connectors, wherein each connector is assigned to a particular group of cells and is arranged between a global bit line and global write-lines and a section of a bit line assigned to a group of cells. Each connector is addressable by two high-order-addresses, a high-order-address for read and a high-order-address for write, to connect said global bit- and write-lines with said section of bit line served by the connector and comprises means to individually access a particular cell of the group of cells accessible via said section of bit line connected with the particular connector. Each connector further comprises means to forward read-signal or write-signals to said particular cell selected.

In an additional preferred embodiment of said memory according to the invention, said means to individually access a particular cell of the group of cells accessible via said section of bit line connected with the connector comprise a section of bit line preferably carried out as a pair of local bit lines connecting the group of cells with said connector.

In an additional preferred embodiment of said memory according to the invention, said means to forward read- or write signals to said particular selected cell comprise a pair of global write-lines common to all connectors in a column, in order to forward write signals to said connectors.

In an additional preferred embodiment of said memory according to the invention, said means to forward read- or write signals to said particular cell selected comprise a global bit line common to all connectors in a column, in order to forward read signals from said connectors.

According to an additional preferred embodiment of the memory according to the invention, two connectors of adjacent groups of cells are combined to one device, in order to increase density of the memory by saving at least one transistor and in order to reduce load on the global bit- and write-lines.

The foregoing, together with other objects, features, and advantages of this invention can be better appreciated with reference to the following specification, claims and drawings.

### BRIEF DESCRIPTION OF THE DRAWINGS

FIGS. 1-3 depict views of a device comprising two connectors to be arranged in a memory according to the invention.

### DETAILED DESCRIPTION

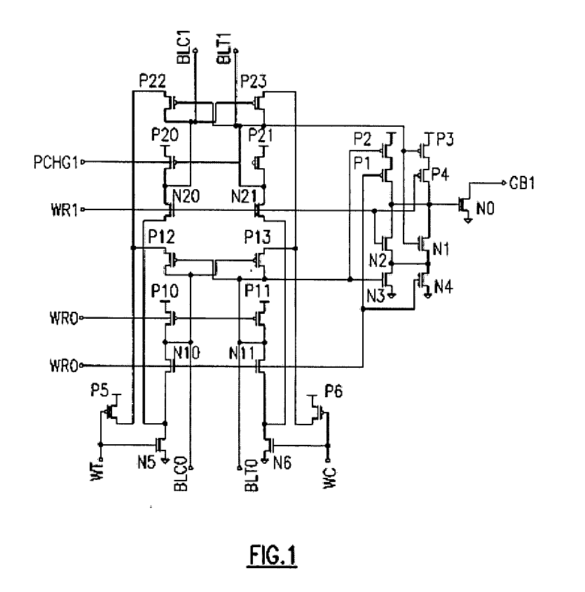

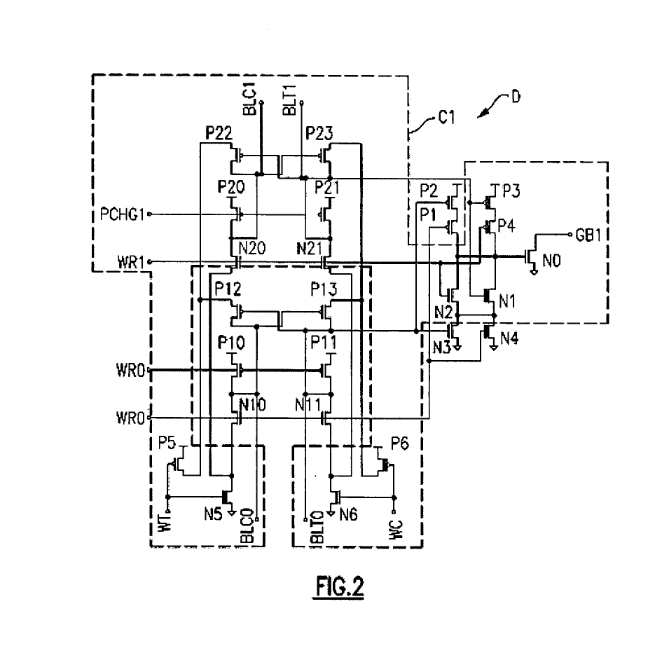

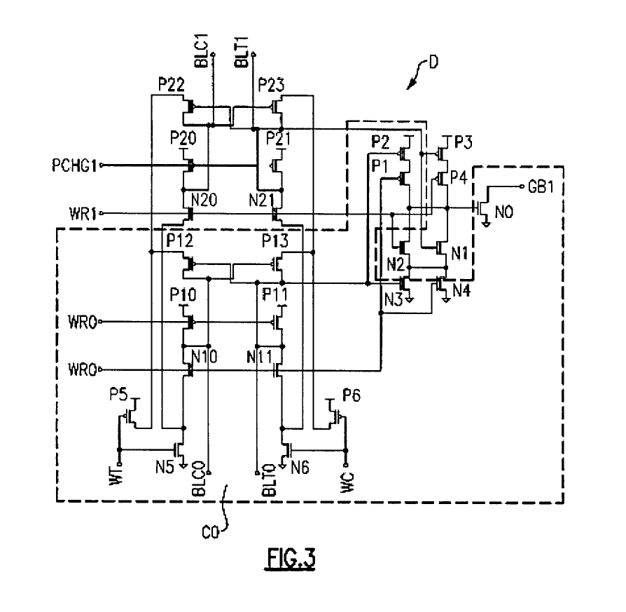

Referring to FIGS. 1-3, the invention applies to a memory as shown in FIG. 1 comprising an array of memory cells organized in bit lines and word lines, whereby the bit lines are subdivided in sections of word lines and whereby the sectioned bit lines are connected to global hit lines “gbl” for read and to global write lines “wt” and “wc” for write by connectors C0 shown in FIG. 3 and C1 shown in FIG. 2. Thereby each section of a bit line is connected to the global lines by a dedicated connector C0, C1. Each section of bit line is carried out as a true/complement pair of local bit lines “blt” (true), “blc” (complement) connecting the group of cells with said connector C0, C1. The connector C0, C1 is made bidirectional and uses high order addresses for the section of bit line connected as disable reset command. Therefore the reset stays active for unselected portions, i.e. sections. The invention extends the operation of such a connector C0, C1 by separating read and write. Disable reset commands are split in two commands and are combined with the high order addresses of the write address port and of the read address port. Thus the connector C0, C1 operates unidirectional either as write-connector or read-connector. Two connectors C0, C1 supplying different sections can be active at a time.

Thus a dual read-write-ports memory-array is achieved with the limitation that read and write has to be done in different sections Exclusive gating of the high-order read- and write-addresses can disable double addressing of a connector C and avoids data destruction. The fully decoded addresses for read and write are combined in a logical OR function and drive two word lines, Address range of a cache is typical 128 or 256, a subsection, i.e. a group of cells assigned to a section of a bit line, typically comprises 16 addresses, Likelihood to hit same address group is small and therefore performance hit is small whereas area saving compared to the use of a so-called 8T eight-transistor cell is large.

FIG. 1 shows two connectors C0, C1 of said kind that enable simultaneous read- and write-operations in different sections accessible via two pairs of local bit lines blt0, blc0, blt1, blc1. The connectors C0, C1 are paired to a device D and placed in the center of two sections serving two groups of 16 cells via ports blt0, blc0 and blt1, blc1, Two connectors C0, C1 are combined for less interruptions of the cell structure and for sharing transistors. Signals pchg0, pchg1 are the logical OR of high-order read- and high-order write-address. None, one or both can be validated with an up level. When turned on positive restore transistors P10, P11 and or P20, P21 are turned off and connected local bit lines blt0, blc0, blt1, blc1 are prepared for read or write. Wr0, wr1 are high order write addresses. None or only one can be activated by turning positive to a ‘1’. Activating prevents propagation of write information to the global bit line “gbl” carrying the read information to outside memory. The global bit line port is named “gbl”. It is pre-charged to a positive level, logically a ‘1’ by a circuit not shown and turned to down level, logically a ‘0’ according to the logical function:

gbl=NOT{{NOT{wr1}AND NOT{blt1))OR {NOT(wr0}AND NOT(blt0}}.

The AND OR invert function is achieved with transistor N0, N1, N2, N3, N4 and P1, P2, P3, P4. As in unselected connectors C0, C1 “blt” stays precharged at ‘1’, only a connector C0, C1 selected by read can switch the global bit line “gbl”.

Active wr0 or wr1 also connect global write-lines wt and “wc” to “blc0” or “blc1” and “blt0” or “blt1”. Write-lines “wt” and “wc” are global and common to all connectors C0, C1 and carry the write information: for write ‘0’ wt=0, wc=1, for write ‘1’ wt=1, wc=0.

Taking ‘1’ as up level and ‘0’ as down level blt0 or blt1 is pulled down with wc=1 via N6 and N11 or N21. Wt=0 turns on P5 and down going blt0 or blt1 turns on transistors P12 or P22 thus pulling up blc0 or blc1 respectively. The forced bit lines switch the selected cell. P6 is kept off. Transistors in series P13 or P23 could be turned on by an “early” read ‘1’ which might occur before the selected cell is switched and which tends to pull down blc0 or blc1, But closed P6 prohibits weakening of pull down action on blt0 or blt1.

Write ‘1’ is the exact compliment operation to write ‘0’. Wc=O and wt=0 cause a half select condition where selected bit lines are operated like during a read but cannot propagate any signal to the global bit line. Cross-coupled transistors P12, P13 or P22, P23 are working as cross-coupled keepers on the bit lines.

In a read-operation the selected cell pulls down either blc or blt and the activated connector propagates the read information to the global bit line gbl according to the logical function above. For connectors C0, C1 in read condition cross-coupled keepers P12, P13 or P22, P23 may be disabled partially depending on global signals wc, wt. As bit lines always start from a precharged up level and an active cell can compensate sufficiently leakage on the local bit line, keepers are not necessary for read.

As it can be seen in FIG. 1, the device D comprises two logical connectors C0, C1 because by combining the two connectors C0, C1 assigned to adjacent groups of 16 cells each, transistors can be saved. This reduces load on global lines and increases density of the memory.

While the present invention has been described in detail, in conjunction with specific preferred embodiments, it is evident that many alternatives, modifications and variations will be apparent to those skilled in the art, in light of the foregoing description. It is therefore contemplated that the appended claims will embrace any such alternatives, modifications and variations as falling within the true scope and spirit of the present invention.

What is claimed is:

1. A memory comprising a plurality of cells accessible by word lines and bit lines, each cell comprising six transistors adapted to both store a bit inserted into the cell during a write operation and affect a signal asserted during a read operation on a bit line coupled to the cell such that the affected signal matches a value of the bit stored in the cell the bit lines of the memory sub-divided into sections assigned to groups of cells, each of said group of cells consisting of equal numbers of said cells, wherein said sections are individually accessible for read or write operations;
the memory adapted to perform a method comprising:
accessing a first cell belonging to a first group; and
simultaneously with said accessing said first cell belonging to said first group, accessing a second cell belonging to a second group, the simultaneously accessing comprising simultaneously performing any one of a write operation or a read operation in the first cell belonging to the first group and performing any one of a write operation or a read operation in the second cell belonging to a second group.

2. The memory according to claim 1, wherein different operations are simultaneously performed, wherein the write operation is performed in the first cell belonging to the first group, and the read operation is performed in the second cell belonging to the second group.

3. The memory according to claim 1, wherein the simultaneously accessing the first cell belonging to the first group and the second cell belonging to the second group is performed by using high-order addresses wherein each high-order address is assigned to a particular section of the bit line.

4. The memory according to claim 3, wherein in order to perform any one of the write operation or the read operation in the first cell belonging to the first group and performing any one of the write operation or the read operation in the second cell belonging to the second group simultaneously, the high-order address used to select a particular section of the bit line is used as a disable reset command whereby the reset stays active for unselected sections, wherein the reset command is split in two commands and the split commands are combined with high-order addresses for read and/or write.

5. The memory according to claim 1, comprising connectors for simultaneously addressing two sections of the bit line, each connector assigned to a group of cells, wherein each connector is arranged between a global bit line, global write lines and a section of a bit line assigned to a group of cells, each connector being addressable by a high-order-address for read and a high-order-address for write to connect said global bit lines and write lines with said section of bit line served by the connector, said connector further comprising means to individually access a particular cell of the group of cells accessible via said section of bit line connected with the connector and means to forward any one of read signals or write signals to said particular cell selected.

6. The memory according to claim 5, wherein said means to individually access a particular cell of the group of cells accessible via said section of bit line connected with the connector comprises a section of bit line consisting of a pair of local bit lines connecting the cells of the group with said connector.

7. The memory according to claim 6, wherein said means to forward said write signals from said particular cell selected to said connectors comprises a pair of global word lines common to all connectors in a column.

8. The memory according to claim 7, wherein said means to forward said read signals from said connectors to said particular cell selected comprise a global bit line {gbl} common to all connectors (C0, C1) in a column.

9. The memory according to one of the claims 8, wherein two connectors {C0, C1} of adjacent groups of cells are combined to one device {D), in order to increase density of the memory.

10. A method for improved performance of a memory, the memory comprising a plurality of cells accessible by word lines and bit lines, wherein each cell comprises six transistors adapted to both store a bit inserted into the cell during a write operation and affect a signal asserted during a read operation on a bit line coupled to the cell such that the affected signal matches a value of the bit stored in the cell, the bit lines of the memory sub-divided into sections assigned to groups of cells, each of said group of cells consisting of equal numbers of said cells, wherein said sections are individually accessible for read or write operations, said method comprising:
accessing a first cell belonging to a first group; and
simultaneously with said accessing said first cell belonging to said first group, accessing a second cell belonging to a second group, the simultaneously accessing comprising simultaneously performing any one of a write operation or a read operation in the first cell belonging to the first group and performing any one of a write operation or a read operation in the second cell belonging to a second group.

11. The method according to claim 10, wherein different operations are simultaneously performed, wherein the write operation is performed in the first cell belonging to the first group, and the read operation is performed in the second cell belonging to the second group.

12. The method according to claim 11, wherein the simultaneously accessing the first cell belonging to the first group and the second cell belonging to the second group is performed by using high-order addresses wherein each high-order address is assigned to a particular section of the bit line.

13. The method according to claim 12, wherein in order to perform any one of the write operation or the read operation in the first cell belonging to the first group and performing any one of the write operation or the read operation in the second cell belonging to the second group simultaneously, the high-order address used to select a particular section of the bit line is used as a disable reset command whereby the reset stays active for unselected sections, wherein the reset command is split in two commands and the split commands are combined with high-order addresses for read and/or write.
